(19) United States
(12) Patent Application Publication
(10) Pub. No.: US 2004/0218366 A1
(43) Pub. Date: Nov. 4, 2004

(54) Multilayer circuit board

(76) Inventor: Wolfgang Speigl, Sinzing-Viehhausen (DE)

Correspondence Address: BAKER BOTTS L.L.P., PATENT DEPARTMENT, 98 SAN JACINTO BLVD., SUITE 1500, AUSTIN, TX, 78701-4039, US

(21) Appl. No.: 10/819,627

(22) Filed: Apr. 7, 2004

(30) Foreign Application Priority Data
Apr. 7, 2003 (DE) DE10315768.9

(51) Int. Cl. H05K 7/20

(52) U.S. Cl. 361/720; 361/707; 361/711

(57) ABSTRACT

Multilayer circuit board (10b) for electrically interconnecting components (12b) of an electronic circuit, wherein one of the components (12b-1) has a cooling plane (14b) which is in planar contact over at least one cooling plane section (16b) of the cooling plane with a metal plane (22b-1) disposed in the topmost circuit board layer (20b-1) and possessing a first electrical potential, wherein there is provided a metal plane (24b-1) possessing a second electrical potential which is in electrical contact with at least one (12b-2) of the components (12b), and wherein there is formed at least one pair of overlapping metal planes from one of the metal planes (22b) possessing the first electrical potential and one of the metal planes (24b) possessing the second electrical potential, the overlap of the two metal planes being at least as large as the cooling plane section (16b).

### PRIORITY

This application claims priority to German application no. 103 15 768.9 filed Apr. 7, 2003.

### TECHNICAL FIELD OF THE INVENTION

The invention relates to a circuit board for electrically interconnecting electronic components disposed on the topside and/or underside of said circuit board.

### BACKGROUND OF THE INVENTION

Circuit boards of this kind have long been customary for industrial production of particularly more complex electronic circuits in which a large number of discrete electronic components have to be interconnected to implement an electronic circuit arrangement.

The advantage here of a multilayer circuit board, i.e. a circuit board having a plurality of circuit board layers electrically insulated from one another, is that it provides greater flexibility in the disposition of conductor tracks (“circuit board layout”). In addition, the electronic components can be disposed with greater packing density on the component side or sides. This is because the conductor tracks can be routed in a plurality of levels, and vertically aligned electrical connections (“through-holes” or “vias”) between conductor tracks disposed in different circuit board layers can be provided at required locations.

In circuit boards, conductor tracks, i.e. electrically conducting paths, also termed conductor planes when they extend over a larger area, are usually provided as metal planes. These are manufactured e.g. by patterned etching of a copper layer.

Components in electronic circuits often have to be cooled during operation. Such components therefore generally have a metal cooling plane which heats up during operation of said component and on which there can be disposed, for example, a cooler for heat transfer. Also known are component cooling planes of this kind which have to be brought into contact with a metal plane of an outer circuit board layer of a circuit board, so that said metal plane dissipates the heat produced or at least distributes it horizontally (“horizontal heat spreading”). Finally it is conceivable to transfer the generated heat vertically through the circuit board to the opposite side of said circuit board by means of the abovementioned through-holes and to establish contact with a cooler on said opposite side. Particularly in this case a housing section, for example, can be used as the cooler.

With many components, an electrical potential containing high frequencies is present on the component cooling plane, e.g. a signal with steep voltage edges. This potential may then be fed to the cooler directly through the cooling measures described or as interference current due to capacitive coupling. If the cooler is connected to a constant reference potential of the electronic circuit, a difficult-to-control interference current loop is produced in which the currents flowing to the cooler flow back over some paths into some parts of the circuit. Consequently, comparatively large parts of the electronic circuit are subjected to high-frequency interference signals and the interference thus propagated. If the cooler is electrically insulated, interference capacitively transmitted from the component to the cooler may be capacitively discharged to ambient.

To summarize, a problem therefore arises with the known circuit boards concerning, on the one hand, heat dissipation (thermal considerations) and, on the other, concerning high-frequency electrical interference which it is necessary to reduce (improving EMC=“electromagnetic compatibility”).

In attempting to solve these two problems, there is in practice a conflict of aims insofar as providing particularly efficient heat dissipation paths (e.g. large metal planes for heat spreading, through-holes for vertical heat transfer, large coolers, etc.) at the same time creates efficient electrical paths for the propagation of electromagnetic interference.

### SUMMARY OF THE INVENTION

The object of the present is therefore to overcome the abovementioned problems and in particular to specify a circuit board in which efficient heat dissipation can be achieved while at the same time suppressing high-frequency electrical interference.

This object can be achieved by a multilayer circuit board for electrically interconnecting electronic components disposed on a topmost layer of a plurality of circuit board layers, comprising at least one component with a cooling plane which heats up during operation of said component and is in planar contact over at least one cooling plane section of said cooling plane with a metal plane disposed in the topmost circuit board layer and possessing a first electrical potential, a metal plane possessing a second electrical potential which is in electrical contact with at least one of the electronic components, and at least one pair of overlapping metal planes which is formed by the metal plane possessing the first electrical potential and the metal plane possessing the second electrical potential, these two metal planes being disposed in directly adjacent circuit board layers and the overlap of these two metal planes being at least as large as the cooling plane section.

The object can also be achieved by a multilayer circuit board for electrically interconnecting electronic components disposed on a topmost layer of a plurality of circuit board layers, comprising at least one component with a cooling plane which heats up during operation of said component and is in planar contact over at least one cooling plane section of said cooling plane with a metal plane disposed in the topmost circuit board layer and possessing a first electrical potential, a metal plane possessing a second electrical potential which is in electrical contact with at least one of the electronic components, wherein the metal plane disposed in the topmost circuit board layer and possessing the first electrical potential is connected via one or more metal through-holes to at least one other metal plane disposed on at least one other of the circuit board layers and likewise possessing the first electrical potential, and/or the metal plane possessing the second electrical potential is connected via one or more metal through-holes to at least one other metal plane disposed on at least one other of the circuit board layers and likewise possessing the second electrical potential, and at least one pair of overlapping metal planes which is formed by one of said metal planes possessing the first electrical potential and one of the metal planes possessing the second electrical potential, these two metal planes being disposed in directly adjacent circuit board layers and the overlap of these two metal planes being at least as large as the cooling plane section.

The cooling plane can be a metal cooling plane. A power component can be provided as the component having the cooling plane. A component can be provided as the component having the cooling plane during the operation of which steep voltage edges occur on the cooling plane. The or at least one of the metal planes possessing the second electrical potential can be provided for thermal contact with a metal cooling plane. The or at least one of the metal planes possessing the first electrical potential and/or the or at least one of the metal planes possessing the second electrical potential can be overlapped by at least one metal plane possessing a potential different from both the first electrical potential and the second electrical potential and disposed in a directly adjacent circuit board layer, the overlap being at least as large as the cooling plane section.

The basic idea of the invention consists in a particular arrangement of metal planes in multilayer circuit boards for spreading and/or feeding back interference currents so as to minimize RFI. With this particular arrangement of planes, at least parts of the interference current originating from the component to be cooled can be fed back in a readily controllable manner, in particular over short paths, so that the circuit itself and the environment are unaffected.

If a cooler is disposed on the circuit board as the heat sink, interference currents of this kind can be fed back bypassing said cooler, this being particularly advantageous in terms of EMC for comparatively large coolers or for electronic circuit housing sections used as coolers.

According to the invention, at least one of the components disposed on a topmost circuit board layer has a cooling plane, e.g. a metal cooling plane, which heats up during operation of said component and which is in planar contact over at least one metal plane section with a metal plane of the topmost circuit board layer possessing a first electrical potential. The term “topmost circuit board layer” here denotes one of the two outermost circuit board layers and is used for easier reference to circuit board layers located further in (“underlying layers”) and for easier reference to the opposite outermost circuit board layer (“lowest layer” or “bottom”).

The topmost circuit board layer is the component side on which the relevant component to be cooled is disposed. This of course does not exclude components also being inserted on the opposite outermost side of the circuit board and the measures according to the invention also being used for one or more of these components.

The term “first electrical potential” is used to denote those metal planes of the circuit board assembly which are directly connected to the cooling plane section of the component cooling plane or indirectly connected to said cooling plane via metal through-holes. This first electrical potential can be, for example, a constant reference potential of the circuit. However, it can also just as well be a time-varying potential, as the e.g. metal cooling plane of a component is often used as a signal-carrying component terminal. This cooling plane is in planar contact over at least one cooling plane section with a metal plane of the topmost circuit board layer, e.g. via one or more soldered connections. A greater or lesser degree of horizontal heat spreading therefore takes place even on this metal plane. In this context it is important that this metal plane be at least as large as the cooling plane section (e.g. the sum of the solder contact areas). If required, vertical heat spreading can take place from this metal plane through one or more metal through-holes to at least one other metal plane therefore likewise possessing the first electrical potential on circuit board layers further below. In order to achieve a greater or lesser degree of horizontal heat spreading here also, these other metal planes must likewise have at least the specified size.

According to the invention, the metal plane possessing the first electrical potential on the topmost circuit board layer and, if present, the other metal planes possessing the first electrical potential are coupled in a particular manner both electrically and thermally to one or more metal planes possessing a second electrical potential. This second electrical potential can also be a constant potential or a time-varying potential and the term serves only to differentiate it from the potential of the abovementioned metal plane(s).

This advantageous coupling is used for heat transmission from the one or more metal planes possessing the first electrical potential, hereinafter also referred to simply as the “first plane array”, to the one or more metal planes possessing the second electrical potential, hereinafter also referred to simply as the “second plane array”. This special coupling between the two plane arrays simultaneously allows a well-defined and easily controllable feedback of high-frequency interference which is transmitted from the component via its cooling plane to the first plane array.

The coupling is realized by implementing at least one pair of overlapping metal planes which is formed from the or one of the abovementioned metal planes possessing the first electrical potential and the or one of the metal planes possessing the second electrical potential, these two metal planes being disposed in directly adjacent circuit board layers and the overlap of these two metal planes being at least as large as the cooling plane section.

At each such pair of overlapping metal planes, heat transfer through the intervening electrical isolation layer takes place because of the spatial proximity (directly adjacent circuit board layers and overlapping) so that heat is advantageously transferred from the first plane array to the second plane array. This spatial proximity of the two metal planes at this “pairing location” simultaneously brings about in practice well-defined capacitive coupling of the high-frequency interference from the first plane array to the second plane array, the interference coupled into the second plane array being able to be fed back in a readily controllable manner, as the second plane array is in electrical contact with at least one of the electronic components, whether it be the component to be cooled itself or another component of the same electronic circuit. This means that an interference current can be fed back in particular over a short path (small current loop) and with low RF emission, thereby enabling the EMC characteristics of the circuit implemented using the circuit board to be improved.

The invention additionally permits the use of smaller electronic components or makes power dissipation problems easier to overcome, as the thermal resistance of the arrangement can be provided lower than for known circuit boards.

The invention further allows an advantageously (for heat spreading) larger-area metal cooling plane in thermal contact with an additional cooler to be provided on an outer side of the circuit board for heat spreading, without appreciable interference being propagated via such a cooler.

For cooling switching transistors (e.g. of a voltage converter), for example, the very efficient heat dissipation provided by the invention allows the switching edges to be provided flatter to prevent RF interference components, as the associated increase in the thermal power dissipation can be controlled by the special plane array in the circuit board.

If additional circuit design measures are required to reduce the radiated interference still further, such as providing so-called snubber networks (e.g. comprising resistors, capacitors and diodes), these measures can be implemented more easily and therefore more inexpensively.

As regards the size of the abovementioned metal planes, in particular the following design features (individually and particularly in combination with one another) have been found to be particularly advantageous for heat dissipation and interference suppression:

a) The metal plane possessing the first electrical potential in the topmost circuit board layer is at least twice, in particular at least five times as large as the cooling plane section.

b) At least one of the possibly provided metal planes possessing the first electrical potential in the other circuit board layers is at least twice, in particular at least five times as large as the cooling plane section.

c) If metal planes possessing the first electrical potential are connected to other circuit board layers by means of through-holes, the number of through-holes connecting two metal planes is at least half as large as the quotient of the smaller of the two metal planes and the area of the cooling plane section.

d) There are provided at least two pairs of overlapping metal planes.

e) For at least one pair of overlapping metal planes, in particular for all the pairs of overlapping metal planes, the overlap of the two opposing metal planes is 50%, in particular at least 70%, of the smaller of these two metal planes.

The circuit board according to the invention is particularly useful in terms of its good heat dissipation characteristics if a power component, in particular a power semiconductor component, is provided as the component having the cooling plane. For example, this can be a switching transistor or a rectifier diode of a switch mode power supply (e.g. DC/DC converter). Alternatively or additionally, this component can be provided as a component during whose operation steep voltage edges are present at the cooling plane, as e.g. in the case of a transistor operated as a switch or e.g. in the case of a component to which a square wave signal is applied. Finally, the use of the invention is also particularly useful for components subjected to high-frequency signals during operation.

A preferred field of application of the invention is to provide a circuit board for a component of the electronics of a motor vehicle, as the thermal and EMC problems outlined above are of major importance here.

In a preferred embodiment, at least one of the metal planes possessing the second electrical potential is provided for a thermal contact, in particular for a planar contact, with a metal cooler. A thermal contact of this kind can be implemented e.g. in a planar manner through a heat-conducting paste or through a metal screwed connection in the known way. In particular, a housing of the relevant electronic circuit can be used as the cooler.

In multilayer circuit boards, as part of the circuit board layout, there are provided particularly large-area metal planes which carry a constant electrical reference potential (e.g. supply potential of the circuit). The large extent of such reference planes is because a large number of the electronic components generally have to be supplied with such reference potentials. These reference planes, which are in practice often useful anyway, can be advantageously used within the scope of the invention, namely as planes of the first plane array, of the second plane array, or as planes which are coupled to one of the two plane arrays via an overlap plane coupling as mentioned above.

If the reference potential is different from the first electrical potential and from the second electrical potential, it is provided in a preferred embodiment that at least one of the metal planes possessing the first electrical potential and/or at least one of the metal planes possessing the second electrical potential is overlapped by at least one of these reference planes, said reference plane being disposed in a directly adjacent circuit board layer and the overlap being at least as large as the cooling plane section.

Preferably the overlap is once again at least 50% of the smaller of the two overlapping planes. It is also conceivable that the potential of a large-area reference plane of this kind constitutes the first electrical potential or the second electrical potential.

In addition to the already mentioned metal through-holes, metal planes of the first and/or second plane array can also be connected to other metal planes of the circuit board via thermally conducting, but electrically poorly conducting or isolating through-holes, in order to provide additional thermal dissipation paths.

Within the scope of the invention, good electrical and thermal conductivity of the metal circuit board constituents provided, particularly conductor tracks or conductor planes, is essential. It is of course conceivable to use another material for these constituents, as long as this electrical and thermal conductivity is guaranteed to a sufficient extent.

### BRIEF DESCRIPTION OF THE DRAWINGS

The invention will now be explained in greater detail using a number of exemplary embodiments and with reference to the accompanying drawings in which:

FIG. 1 shows a perspective schematic view of a circuit board for explaining the basic idea of the invention using a two-layer circuit board as an example.

FIG. 2 shows a perspective schematic view of a circuit board for explaining the basic idea of the invention using a four-layer circuit board as an example.

FIG. 3 shows a sectional view of a two-layer circuit board according to another embodiment,

FIG. 3a shows a schematic plan view of the circuit board from FIG. 3,

FIG. 4 shows a sectional view of a four-layer circuit board according to another embodiment, and

FIG. 5 shows a sectional view of a four-layer circuit board according to another embodiment.

### PREFERRED EMBODIMENTS OF THE INVENTION

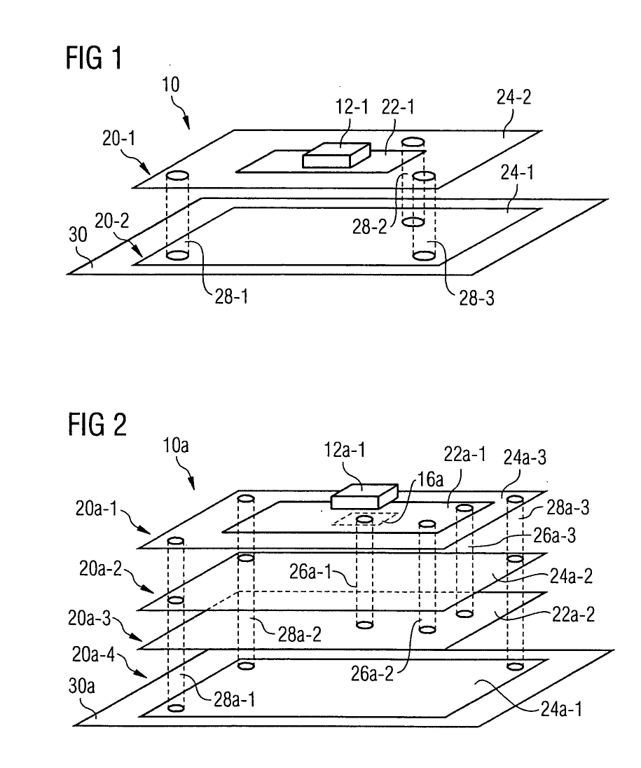

FIG. 1 is a highly schematic representation of a circuit board 10 for electrically interconnecting electronic components forming an electronic circuit, only one of which components (labeled 12-1) is shown in the Figure.

The circuit board 10 comprises two circuit board layers 20-1 and 20-2 electrically insulated from one another by an isolation layer (e.g. of epoxy resin) which is not shown. For the sake of representational clarity, the circuit board structure is shown in an “exploded” view (spacing between the layers 20-1 and 20-2 enlarged). In addition, only the metal planes essential for understanding the invention are schematically shown. In practice the thickness of the circuit board is typically in the range 1 to 2 mm.

The heat produced during operation of the component 12-1 is transferred via an electrically conducting (in this case metal) cooling plane of the component to a metal plane 22-1 formed by the topmost circuit board layer 20-1 and providing horizontal heat spreading. For power semiconductors the size of the cooling plane is typically e.g. 0.1 to 2 cm².

The lower circuit board layer 20-2 which is therefore directly vertically adjacent to the topmost circuit board layer 20-1 has a metal plane 24-1 onto which the heat is transferred by vertical heat transfer through the isolation layer. However, because of this isolation, the potential of the upper metal plane 22-1 (first potential) is not transferred to the lower metal plane 24-1 which possesses a different potential (second electrical potential). Because of a large horizontal overlap of the metal planes 22-1 and 24-1 as shown, high-frequency interference emitted by the component 12-1 is transmitted via the plane 22-1 by capacitive coupling to the plane 24-1. In order to feed back an associated interference current in as well defined a manner as possible, metal through-holes 28-1, 28-2 and 28-3 are provided which connect the plane 24-1 to a metal plane 24-2 likewise possessing the second electrical potential and in electrical contact with at least one of the electronic components of the circuit, whether it be the component 12-1 or another component. In any case, this structure results in good heat dissipation combined with a reduction in emitted interference through a locally more or less tightly limited routing of interference currents. There can be formed a very small current loop from the component 12-1 via capacitive coupling to the lower plane 24-1 and on via the through-holes 28-1 to 28-3 to the plane 24-2 and directly back to the component 12-1 or indirectly via other circuit components.

The heat transferred to the lower metal plane 24-1 is dissipated via a planar contact with the surface of a cooler 30. There is no significant radiation of interference through this cooler 30, as the interference currents are fed back over a short path through the through-holes 28-1 to 28-3 in a low impedance and low inductance manner.

In the following description of other exemplary embodiments, the same reference figures will be used for equivalent components, but with a lower-case letter added to distinguish the relevant embodiment, essentially only the differences compared to the already described embodiments being examined and, moreover, with reference specifically to the description of foregoing embodiments.

The reference figures of components of which there are more than one in an embodiment, but which are functionally equivalent, are continuously numbered (supplemented in each case by hyphen and a serial number). Hereinafter reference will also be made to individual such components or to the totality of such components by means of the unsupplemented reference figure.

The example in FIG. 2 illustrates the coupling between a first plane array 22a and a second plane array 24a as exemplified by a four-layer circuit board 10a comprising circuit board layers 20a-1 to 20a-4. The underside of component 12a-1 to be cooled is soldered over its entire surface to a metal plane 22a-1 of the topmost circuit board layer 20a-1, so that in this example the component cooling plane altogether forms a cooling plane section 16a in planar contact with the metal plane 22a-1. For horizontal heat spreading, the plane 22a-1 is provided significantly larger than said cooling plane section 16a. The plane 22a-1 possessing the first electrical potential is thermally and electrically connected via the metal through-holes 26a (in this case 26-1 to 26a-3) to a metal plane 22a-2 of the third circuit board layer 20a-3. Through-holes passing through all the circuit board layers 20a are generally used here. The two planes 22a-1 and 22a-2 form a first plane array 22a. A second plane array 24a possessing the second electrical potential is formed by metal planes 24a-1 to 24a-3 which are thermally and electrically interconnected by means of through-holes 28a (in this case 28a-1, 28a-2 and 28-3).

In contrast to the arrangement described with reference to FIG. 1, there is here formed a plurality of overlapping pairs of metal planes which are used for interference current feedback, namely between the planes 22a-1 and 24a-2, the planes 24a-2 and 22a-2 and the planes 22a-2 and 24a-1.

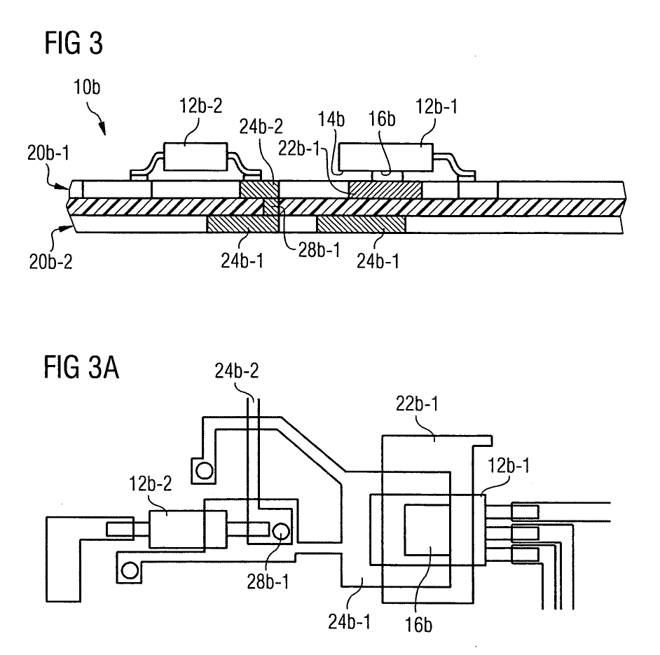

FIGS. 3 and 3a illustrate another embodiment of a two-layer circuit board 10b having a component 12b-1 to be cooled on the upper circuit board layer 20b-1. On a cooling plane section 16b, a cooling plane 14b of the component 12b-1 is in planar thermal and electrical contact with a metal plane 22b-1 via a soldered connection. As the plan view in FIG. 3a shows, this metal plane 22b-1 is some six times as large as the cooling plane section 16b, so that horizontal heat spreading takes place even here.

The metal plane 22b-1 is overlapped in the horizontal direction by a metal plane 24b-1 located in the lower circuit board layer 20b-2, so that heat transfer takes place through an interposed isolation layer into this lower layer 24b-1. The interference currents capacitively transferred to the plane 24b-1 are fed back via another metal plane 24b-2 of the second metal plane array 24b, the plane 24b-1 being electrically connected to the plane 24b-2 via a through-hole 28b-1, and on to another component 12b-2 of the electronic circuit.

This short feedback path allows a cooler (not shown in FIGS. 3 and 3a) to be disposed on the underside of the circuit board 10b without appreciable interference being radiated via such a cooler.

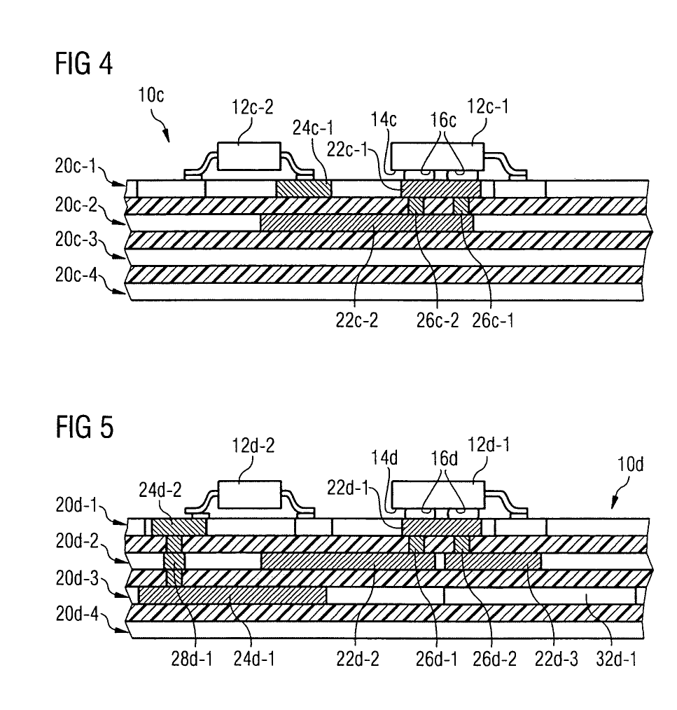

FIG. 4 shows an embodiment of a circuit board 10c having four circuit board layers 20c-1 to 20c-4 in which the component 12c-1 to be cooled is soldered via two cooling plane sections 16c in a planar manner onto a metal plane 22c-1 of the topmost layer 20c-1. The heat transferred thereto is first transferred via through-holes 26c-1 and 26c-2 to a plane 22c-2 of the second circuit board layer 20c-2 and horizontally spread. For interference current feedback, this plane 22c-2 together with a plane 24c-1 again form a pair of overlapping metal planes. By means of this layering a capacitor is implemented which provides a low-impedance leakage path for the current caused by a rapid voltage variation.

FIG. 5 shows an embodiment of a circuit board 10d in which the heat transferred to a metal plane 22d-1 of the first layer 20d-1 is transferred via through-holes 26d-1 and 26d-2 to two metal planes 22d-2 and 22d-3 of the second layer 20d-2.

The planes 22d-2 and 24d-1 together again form a pair of overlapping metal planes wherein interference currents are fed back from the plane 24d-1 via a through-hole 28d-1 to a metal plane 24d-2 of the first layer 20d-1 and therefore back to the electronic circuit.

In addition, the metal plane 22d-3 and a reference potential plane 32d-1 in the directly adjacent layer 20d-3 together form another pair of overlapping metal planes via which a small portion of the interference currents is fed back into the electronic circuit, the reference potential plane 32d-1 possessing an electrical potential which is different from the electrical potential of both the first plane array 22d and the second plane array 24d.

I claim:

1. A multilayer circuit board for electrically interconnecting electronic components disposed on a topmost layer of a plurality of circuit board layers, comprising:
at least one component with a cooling plane which heats up during operation of said component and is in planar contact over at least one cooling plane section of said cooling plane with a metal plane disposed in the topmost circuit board layer and possessing a first electrical potential,
a metal plane possessing a second electrical potential which is in electrical contact with at least one of the electronic components, and
at least one pair of overlapping metal planes which is formed by the metal plane possessing the first electrical potential and the metal plane possessing the second electrical potential, these two metal planes being disposed in directly adjacent circuit board layers and the overlap of these two metal planes being at least as large as the cooling plane section.

2. The circuit board according to claim 1, wherein the cooling plane is a metal cooling plane.

3. The circuit board according to claim 1, wherein a power component is provided as the component having the cooling plane.

4. The circuit board according to claim 1, comprising a component, as the component having the cooling plane, during the operation of which steep voltage edges occur on the cooling plane.

5. The circuit board according to claim 1, wherein the or at least one of the metal planes possessing the second electrical potential is provided for thermal contact with a metal cooling plane.

6. The circuit board according to claim 1, wherein the or at least one of the metal planes possessing the first electrical potential and/or the or at least one of the metal planes possessing the second electrical potential is overlapped by at least one metal plane possessing a potential different from both the first electrical potential and the second electrical potential and disposed in a directly adjacent circuit board layer, the overlap being at least as large as the cooling plane section.

7. A multilayer circuit board for electrically interconnecting electronic components disposed on a topmost layer of a plurality of circuit board layers, comprising:
at least one component with a cooling plane which heats up during operation of said component and is in planar contact over at least one cooling plane section of said cooling plane with a metal plane disposed in the topmost circuit board layer and possessing a first electrical potential,
a metal plane possessing a second electrical potential which is in electrical contact with at least one of the electronic components,
wherein the metal plane disposed in the topmost circuit board layer and possessing the first electrical potential is connected via one or more metal through-holes to at least one other metal plane disposed on at least one other of the circuit board layers and likewise possessing the first electrical potential, and/or the metal plane possessing the second electrical potential is connected via one or more metal through-holes to at least one other metal plane disposed on at least one other of the circuit board layers and likewise possessing the second electrical potential, and
at least one pair of overlapping metal planes which is formed by one of said metal planes possessing the first electrical potential and one of the metal planes possessing the second electrical potential, these two metal planes being disposed in directly adjacent circuit board layers and the overlap of these two metal planes being at least as large as the cooling plane section.

8. The circuit board according to claim 7, wherein the cooling plane is a metal cooling plane.

9. The circuit board according to claim 7, wherein a power component is provided as the component having the cooling plane.

10. The circuit board according to claim 7, comprising a component, as the component having the cooling plane, during the operation of which steep voltage edges occur on the cooling plane.

11. The circuit board according to claim 7, wherein the or at least one of the metal planes possessing the second electrical potential is provided for thermal contact with a metal cooling plane.

12. The circuit board according to claim 7, wherein the or at least one of the metal planes possessing the first electrical potential and/or the or at least one of the metal planes possessing the second electrical potential is overlapped by at least one metal plane possessing a potential different from both the first electrical potential and the second electrical potential and disposed in a directly adjacent circuit board layer, the overlap being at least as large as the cooling plane section.
